(19) United States
(12) Patent Application Publication
(10) Pub. No.: US 2008/0007168 A1
(43) Pub. Date: Jan. 10, 2008

(54) Tandem Organic Electroluminescent Element and Use of the Same

(75) Inventors: Chung-Chun Lee, Yunlin County (TW); Hsing-Chuan Li, Taoyuan City (TW)

Correspondence Address: WELLS ST. JOHN P.S., 601 W. FIRST AVENUE, SUITE 1300, SPOKANE, WA, 99201, US

(73) Assignee: AU Optronics Corp., Hsinchu (TW)

(21) Appl. No.: 11/555,395

(22) Filed: Nov. 1, 2006

(30) Foreign Application Priority Data
Jul. 7, 2006 (TW) 095124970

(51) Int. Cl. H01L 51/52; H01L 51/54

(52) U.S. Cl. 313/506; 428/690; 428/917; 313/503; 257/E51.019; 257/E51.049

(57) ABSTRACT

A tandem organic electroluminescent element for use in an organic electroluminescent display is provided. The organic electroluminescent element comprises an anode, a cathode, a first organic electroluminescent unit, a second organic electroluminescent unit, and a connecting layer. Both the first organic electroluminescent unit and the second organic electroluminescent unit are disposed between the anode and the cathode. The connecting layer is between the first and second units, and comprises a bipolar organic compound and a conductive dopant.

This application claims the benefit from the priority of Taiwan Patent Application No. 095124970 filed on Jul. 7, 2006.

### BACKGROUND OF THE INVENTION

1. Field of the Invention

The present invention relates to a tandem organic electroluminescent element, and more particularly, to a tandem organic electroluminescent element for use in an organic electroluminescent display.

2. Descriptions of the Related Art

Because organic electroluminescent devices are known for their high brightness, high, contrast, thinness, wide temperature range, lightness, self-luminosity, unlimited viewing angle, easy manufacturing process and high response rate, they have become an important field in worldwide technology development. These devices also consume low levels of power, lack a need for a backlight source and have no viewing angle limitation. The flat panel display industrial field adds great importance to the organic electroluminescent devices. There are two types of technology in organic electroluminescent devices according to the type of organic electroluminescent materials they use. The first type uses small molecules as the material of the organic light emitting layer, and is generally called an organic light emitting diode (OLED) or an organic electroluminescence. The second type uses π-conjugate polymers as the material of the organic light emitting layer and is generally called a polymer light emitting diode (PLED) or a light emitting polymer (LEP).

Generally, the organic electroluminescent device comprises an anode, a cathode, and light emitting unit(s) disposed between the anode and the cathode. The operating principle of the device is described as follows. Electrons and holes are injected and transmitted in the device under the electric field. Electrons and holes recombine into excitons as they meet in the light emitting unit(s). Excitons transfer energy to light emitting molecules in the light emitting units under the electric field. The light emitting molecules release the energy in the form of light. The light emitting units of a conventional organic electroluminescent device comprise a multilayer structure with a hole transporting layer (HTL), a light emitting layer (EL), and an electron transporting layer (ETL). The method of manufacture is illustrated as follows. The HIL is formed by evaporation on the anode, which is made of indium tin oxide (ITO). Then, the EL and ETL are formed by evaporation subsequently. Finally, an electrode is formed on the ETL by evaporation as the cathode. In order to improve the efficiency of the carriers, electrons and holes, some organic materials may be disposed by evaporation between the anode and the hole transporting material as a hole injection layer (HIL), between the cathode and the electron transporting material as, an electron injection layer (EIL), or between the EL and the electron transporting material as a hole blocking layer (HBL). Accordingly, the driving voltage would be decreased, and the carrier recombination probability would be improved thereby.

To further improve the efficiency of the organic electroluminescent device, a tandem organic electroluminescent device comprising a plurality of continuously connected EL units between the anode and the cathode has been disclosed. Moreover, the EL units connect with each other via connecting layers. To improve the efficiency of the organic electroluminescent device, the ability to transport electrons and holes to the ETL and HTL respectively is required of the connecting layers that are configured to con sect the EL units. In general, the connecting layers should have a high optical transparency and a high carrier transport rate to ensure that the organic electroluminescent device achieves expected efficiency.

One conventional connecting layer is a doped organic layer. The doped organic layer comprises at least one N type doped organic layer, a P type doped organic layer, or a combination of the N and P type doped organic layers to speed up the carrier transport rate. When connecting the N type doped organic layer to the P type doped organic layer, a P-N junction would be formed. Accordingly, the carrier transport efficiency would be improved. An N type doped organic layer refers to an organic layer with characteristics of a semiconductor after being doped, and is mainly used for transporting electrons. A P type doped organic layer refers to an organic layer with characteristics of a semiconductor after being doped, and is mainly used for transporting holes.

The operational stability of the tandem organic electroluminescent device depends on the stability of the connecting layer. The operating voltage would change according to the connecting layer's capability to provide efficient electron and hole injection abilities. Diffusion driven by temperature or electric field would occur as two different substances are very close, and thus the interface between the substances would fade. When applying an N dopant or a P dopant to manufacture the tandem organic electroluminescent device, the injection ability of the connecting layer may be weakened due to the diffusion. Particularly, the operating electric field of the tandem organic electroluminescent device is higher than that of general organic electroluminescent devices; thus, the above recited situation would happen much more easily.

Another type of connecting layer in conventional tandem organic electroluminescent devices is a metal or metal compound layer with a high work function (higher than 4 eV) and a surface resistance of over 100 kΩ/□ as shown in U.S. application Ser. No. 10/857,516. Such connecting layer could effectively enhance the stability of this tandem organic electroluminescent device. The resistance of the recited metal-containing connecting layer is lower than the organic-containing connecting layer, so the carriers can be injected easily. However, crosstalk between pixels would result. The lateral resistance of the connecting layer should be at least eight times the resistance of the tandem organic electroluminescent device, so as to decrease the lateral current that may cause the crosstalk of adjacent pixels to be 10% of a current required for driving pixels. Generally, a static resistance of a conventional organic electroluminescent device is about thousands ohms, and a resistance of tandem organic electroluminescent device is about ten thousands ohms or more. Therefore, the lateral resistance of the connecting layer is at least higher than ten thousands ohms. The surface resistance depends on the resistance and film thickness. If a metal connecting layer is chosen, either the film thickness should be thinner or the connecting layers of the different pixels should be blocked with a pattern to increase the resistance. However, the reproducibility of the manufacture of a thin connecting layer is low. In addition, a patterning process requires a shadow mask and is unsuitable for the manufacture of a large scale panel. Moreover, the metal-comprised connecting layer has bad transparency and tends to laterally leak electricity.

With the above illustrations, the current connecting layers used in a tandem organic electroluminescent device are either doped organic layers whose carrier injection ability tends to be weakened by diffusion, or high work function metal or metal compound layers with bad transparency and lateral electricity leakage. These problems make the current tandem organic electroluminescent device ill-fitted for this industrial field. Thus, the industrial field urgently requires a connecting layer, with high transparency and a high carrier transport rate, which can further improve or prevent problems of the current connecting layer, such as crosstalk, weakened carrier injection abilities, bad reproducibility resulting from overly thin metal, bad transparency, and/or lateral leakage of electricity.

### SUMMARY OF THE INVENTION

An object of this invention is to provide a tandem organic electroluminescent element. The tandem organic electroluminescent element comprises an anode, a cathode, a first organic electroluminescent unit, a second organic electroluminescent unit, and a connecting layer. The first organic electroluminescent unit is disposed between the anode and the cathode. The second organic electroluminescent unit is disposed between the anode and the cathode. The connecting layer is disposed between the first unit and the second unit. The connecting layer comprises a bipolar organic compound and a conductive dopant. The connecting layer has high transparency and a high carrier transport rate. The tandem organic electroluminescent element including the connecting layer can improve the following problems: crosstalk, weakened carrier injection ability, bad reproducibility resulting from overly thin metal, bad transparency, and/or lateral electricity leakage. The luminous efficiency of the element would be improved thereby.

Another object of this invention is to provide an organic electroluminescent display. The organic electroluminescent display comprises the tandem organic electroluminescent element as recited above. With this tandem organic electroluminescent element, crosstalk, weakened carrier injection ability, bad reproducibility resulting from overly thin metal, bad transparency, and/or easily lateral electricity leakage would be improved. The tandem organic electroluminescent element according to the present invention has high transparency and a high carrier transport rate which farther improves the interior luminous efficiency of a display comprising the element.

The present invention will become apparent from the description of the preferred but non-limiting embodiments accompanying the appended drawings.

### BRIEF DESCRIPTION OF THE DRAWINGS

FIG. 1 shows a schematic view of the tandem organic electroluminescent element in accordance with a first embodiment of the present invention;

FIG. 2 shows a schematic view of the tandem organic electroluminescent element in accordance with a second embodiment of the present invention;

FIG. 3A shows a comparison of a voltage-current density between the tandem organic electroluminescent elements having connecting layers with different materials and an organic electroluminescent element with a single organic electroluminescent unit;

FIG. 3B shows a comparison of a voltage-luminance density between tandem organic electroluminescent elements having connecting layers with different materials and an organic electroluminescent element with a single organic electroluminescent unit;

FIG. 3C shows a comparison of a luminance efficiency-luminance density between tandem organic electroluminescent elements having connecting layers with different materials and an organic electroluminescent element with a single organic electroluminescent unit;

FIG. 3D shows a comparison of a luminance-CIE value between the tandem organic electroluminescent elements having connecting layers with different materials and an organic electroluminescent element with a single organic electroluminescent unit; and

FIG. 4 shows a schematic view of the tandem organic electroluminescent element in accordance with a fourth embodiment of the present invention.

### DESCRIPTION OF THE PREFERRED EMBODIMENT

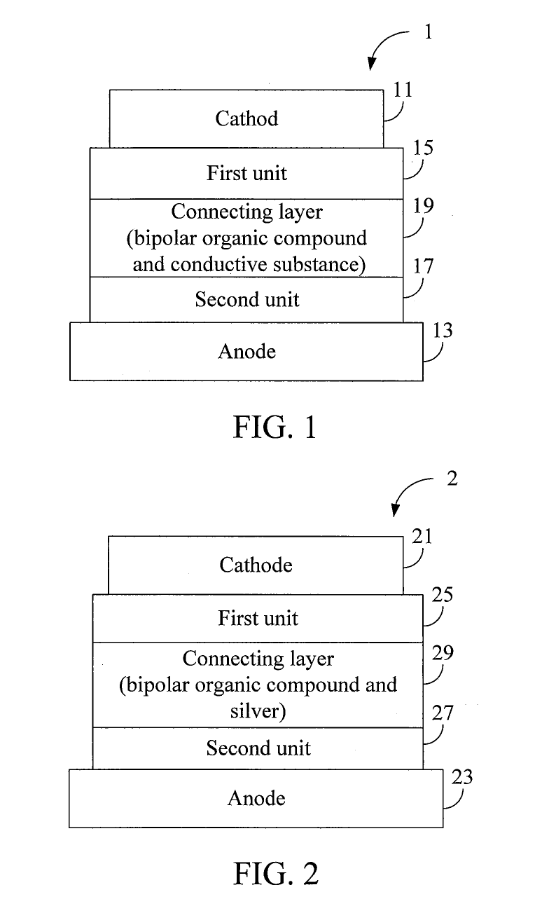

FIG. 1 shows a tandem organic electroluminescent element according to a first embodiment of the present invention. The tandem organic electroluminescent element 1 comprises a cathode 11, an anode 13, a first organic electroluminescent unit 15, a second organic electroluminescent unit 17, and a connecting layer 19. The first unit 15 and the second unit 17 are disposed between the cathode 11 and the anode 13, and the connecting layer 19 is disposed between the first unit 15 and the second unit 17.

For a tandem organic electroluminescent element 1, the anode 13 comprises material(s) with relatively high work function, and the cathode 11 comprises material(s) with relatively low work function. The limitations of the electrodes are that one of the cathode 11 and the anode 13 is a transparent electrode, and the other is either a transparent electrode or an opaque electrode. For example, ITO may be used as the material of the transparent electrode as the anode 13, and materials, such as magnesium, magnesium-silver alloy, calcium, lithium-aluminum alloy, etc., may be used as the material of cathode 11.

The first organic electroluminescent unit 15 and the second organic electroluminescent unit 17 can be any known organic electroluminescent unit. The first and the second organic electroluminescent units, 15, 17 comprise a light emitting layer, and optionally has a multilayer structure that further comprises any one or more of the following layers: an EIL, an ETL, a HTL, a HIL, an electron blocking layer (EBL), or a hole blocking layer (HBL). For example, the multilayer structure is, but not limited to, HTL/EL/ETL, HIL/HTL/EL/ETL, HIL/HTL/EL/ETL/EIL, HIL/HTL/EBL or HBL/EL/ETL/EIL, HIL/HTL/EL/HBL/ETL/EIL, etc. For a tandem organic electroluminescent element, the structure or the material of each tandem organic electroluminescent unit can be identical or different only if the unit has the required electron and hole transport ability.

The connecting layer 19 comprises a bipolar organic compound and a conductive dopant. Any bipolar organic compound with at least 1×10⁻⁷ mm²/V·sec carrier mobility is suitable for the present invention. For example, the bipolar organic compound is made of, but not limited to, anthracene derivatives, fluorene derivatives, spirofluorene derivatives, pyrene derivatives, oligomer or a mixture thereof. More specifically, the connecting layer 19 may use an anthracene derivative, such as 9,10-di-(2-naphthyl) anthracene (ADN), 2-(t-Butyl)-9,10-di(2-naphthyl)anthracene (TBADN), or 2-methyl-9,10-di(2-naphthyl) anthracene (MADN) as the bipolar organic compound.

The conductive dopant of the connecting layer 19 can be any proper conductive metal or metal oxide only if the transparency and the conductivity of the materials are suitable. For example, the materials can be, but not limited to, metals such as aluminum, calcium, silver, nickel, titanium, magnesium, or an alloy thereof, metal compounds such as ITO, ZnO:Al, ZnO, InN, SnO₂, or a combination of the recited metals and metal compounds. Because of the poor transparency, the concentration of the metal should not be too high. Furthermore, lateral electricity leakage would occur as the concentration of the conductive dopant is too high, resulting in decreased efficiency of the organic electroluminescent element. Based on the aforementioned considerations, the concentrations of the conductive dopants in the connecting layer 19 is generally present in an amount ranging from 5% to 65%, preferably from 10% to 60%, and more preferably from 20% to 50%.

When mixing the conductive dopants and the bipolar organic compound, the considerations of the whole conductivity of the connecting layer 19 comprise the following: conductivity of the conductive substances, thickness of the connecting layer 19, and concentration of the conductive substances. The conductivity of the connecting layer would be optimized by well formulating these three considerations.

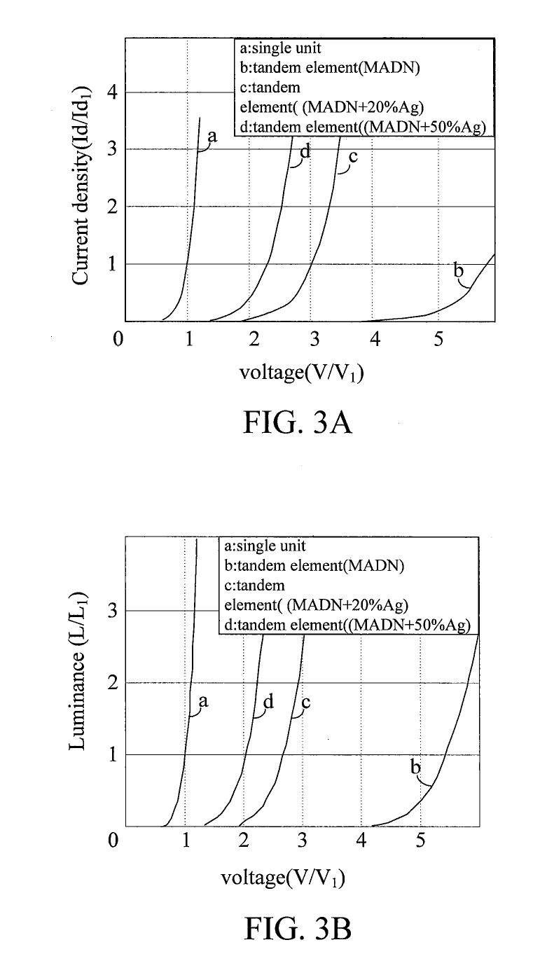

FIG. 2 shows a tandem organic electroluminescent element according to a second embodiment of the present invention. The tandem organic electroluminescent element 2 comprises a cathode 21, an anode 23, a first organic electroluminescent unit 25, a second organic electroluminescent unit 27, and a connecting layer 29. The first unit 25 and the second unit 27 are disposed between the cathode 21 and the anode 23, and the connecting layer 29 is disposed between the first unit 25 and the second unit 27. The connecting layer 29 comprises a bipolar organic compound, and a conductive dopant. The bipolar organic compound is MADN, while the conductive dopant is silver as shown in FIG. 2. Preferably, the concentration of silver in the connecting layer 29 ranges from 10% to 60%, and more preferably from 20% to 50%.

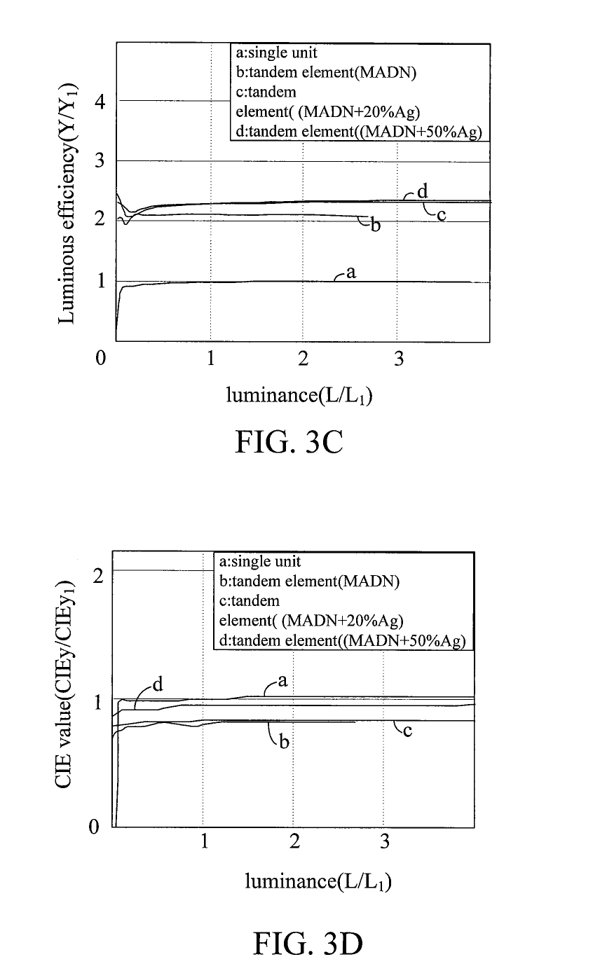

The efficacy of the tandem organic electroluminescent element 2 is shown in FIG. 3A to FIG. 3D. FIG. 3A shows a voltage-current density relationship in graphic form. The horizontal axis and the longitudinal axis represent ratios based on the current density Id₁ mm·A/cm² of an organic electroluminescent element comprising a single organic electroluminescent unit under the voltage V₁V. FIG. 3B shows a voltage-luminance relationship in graphic form. The horizontal axis and the longitudinal axis represent ratios based on the luminance L₁ cd/m² of an organic electroluminescent element comprising a single organic electroluminescent unit under the voltage V₁V. FIG. 3C shows a luminous efficiency-luminance relationship in graphic form. The horizontal axis and the longitudinal axis represent ratios based on the luminous efficiency Y₁ cd/A of an organic electroluminescent element comprising a single organic electroluminescent unit under the luminance L₁ cd/m². FIG. 3D shows a luminance-CIE value relationship in graphic form. The horizontal axis and the longitudinal axis represent ratios based on the CIE value CIE_{y1} cd/m² of an organic electroluminescent element comprising a single organic electroluminescent unit under the luminance L₁ cd/m².

Referring to FIG. 3A to FIG. 3D, line a stands for performance of an organic electroluminescent element having a single organic electroluminescent unit. Line b, line c, and line d stand for performance of three different tandem organic electroluminescent elements 2, wherein each element comprises the first unit 25, the second unit 27, and a connecting layer 29 disposed between the first units 25 and the second units 27. The connecting layers 29 of the three elements are made of MADN (line b), MADN doped 20% silver (line c), and MALDN doped 50% silver (line d), respectively. The structure and material of the first unit 25 and the second unit 27 are the same as that of the single organic electroluminescent unit.

As shown in FIG. 3C, tandem organic electroluminescent units provide higher luminous efficiency than a single organic electroluminescent unit (line b and line a). The use of a combination of a bipolar organic compound and a conductive dopant in the connecting layer between tandem organic, electroluminescent units would provide better luminous efficiency (line c and line d). Referring to FIG. 3A and FIG. 3B, the tandem organic electroluminescent units provide better luminous efficiency, but require a much higher voltage for generating a current identical to that of a single unit (line b and line a). However, the application of a combination of the bipolar organic compound and the conductive dopant in the connecting layer would efficiently prevent the aforementioned disadvantages (line c and line d). Furthermore, the use of a single electroluminescent unit is not substantially different from that of a tandem organic electroluminescent units in the CIE value (line a and line b) as shown in FIG. 3D, even if a combination of a bipolar organic compound and a conductive dopant is used in the connecting layer between the tandem electroluminescent units (line c and line d).

Moreover, because the connecting layer of the tandem organic electroluminescent element of the present invention comprises both a metal conductive substance and another component, there is relatively high resistance, low lateral currents and nonoccurrence of crosstalk. Given the above, the tandem organic electroluminescent element of the invention improves the luminous efficiency effectively without affecting the transparency. It also avoids weakened carrier injection ability, crosstalk, and/or lateral electricity leakage.

A third embodiment of the present invention is an organic electroluminescent display. The organic electroluminescent display comprises a plurality of tandem organic electroluminescent elements as recited above and a plurality of substrates. The substrate comprises a plurality of thin film transistors, wherein the plurality of thin film transistors are electrically connected to a plurality of electrodes of the tandem organic electroluminescent elements. With this tandem organic electroluminescent element, crosstalk, weakened carrier injection ability, bad reproducibility resulting from overly thin metal, bad transparency, and/or lateral electricity leakage would be improved. The present invention has high transparency and a high carrier transport rate which further improves the interior luminous efficiency of the display.

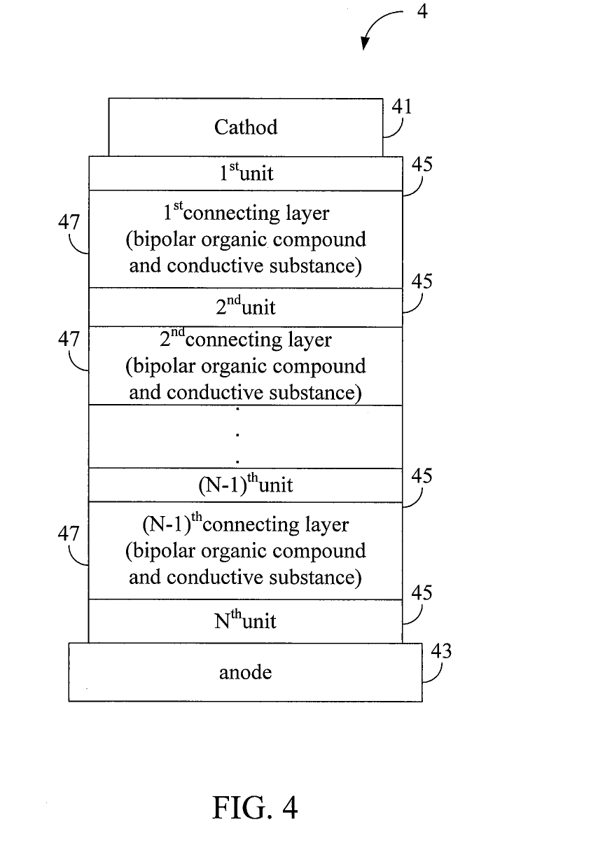

Though the embodiments illustrated for the present invention show a tandem organic electroluminescent element comprising an anode, a cathode, a first organic electroluminescent unit, a second organic electroluminescent unit, and a connecting layer, the people skilled in this field would appreciate the workability of a fourth embodiment of the present invention, wherein a tandem organic electroluminescent element 4 comprises an anode 41 a cathode 43, N organic electroluminescent elements 45, and (N−1) connecting layers 47, as shown in FIG. 4. N is an integer larger than 2.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A tandem organic electroluminescent element, comprising:
an anode;
a cathode;
a first organic electroluminescent unit and a second organic electroluminescent unit disposed between the anode and the cathode; and
a connecting layer disposed between the first organic electroluminescent unit and the second organic electroluminescent unit, wherein the connecting layer comprises a bipolar organic compound and a conductive dopant.

2. The tandem organic electroluminescent element as claimed in claim 1, wherein the conductive dopant is selected from the group consisting of metals and metal compounds.

3. The tandem organic electroluminescent element as claimed in claim 2, wherein the conductive dopant is a metal.

4. The tandem organic electroluminescent element as claimed in claim 3, wherein the metal is silver (Ag).

5. The tandem organic electroluminescent element as claimed in claim 1, wherein the concentration of the conductive dopant in the connecting layer ranges from 10% to 60%.

6. The tandem organic electroluminescent element as claimed in claim 1, wherein the concentration of the conductive dopant ranges from 20% to 50%.

7. The tandem organic electroluminescent element as claimed in claim 1, wherein the bipolar organic compound is 2-methyl-9,10-di(2-naphthyl) anthracene (MADN).

8. A tandem organic electroluminescent display comprising the organic electroluminescent element as claimed in claim 1.

9. The tandem organic electroluminescent display as claimed in claim 8, further comprising a substrate comprising a thin film transistor, wherein the thin film transistor is electrically connected to an electrode of the tandem organic electroluminescent element.
